(19) United States
(12) Patent Application Publication
(10) Pub. No.: US 2025/0374677 A1
(43) Pub. Date: Dec. 4, 2025

(54) DISPLAY DEVICE AND MANUFACTURING METHOD OF THE SAME

(71) Applicant: Samsung Display Co., LTD., Yongin-si (KR)

(72) Inventors: Young Min KIM, Yongin-si (KR); Shin Tack KANG, Yongin-si (KR); Hyun-Seok KIM, Yongin-si (KR); HYUN-SUK PARK, Yongin-si (KR); Seung Jun YU, Yongin-si (KR); SARAH LEE, Yongin-si (KR); Hyun Chul JEONG, Yongin-si (KR)

(21) Appl. No.: 19/078,585

(22) Filed: Mar. 13, 2025

(30) Foreign Application Priority Data
Jun. 3, 2024 (KR) 10-2024-0072323

(51) Int. Cl. H10D 86/40; H01L 25/16; H10D 86/01; H10D 86/60

(52) U.S. Cl. CPC H10D 86/441; H01L 25/167; H10D 86/0212; H10D 86/0221; H10D 86/60

(57) ABSTRACT

A display device includes a substrate including a display area and a non-display area, a light emitting element positioned in the display area and an encapsulation layer overlapping the light emitting element and a plurality of pad electrodes positioned in the non-display area of the substrate, wherein the side of the pad electrode facing the edge of the substrate is covered with an interlayer, the residual layer of the encapsulation layer is not positioned on the upper surface of the pad electrode, and the residual layer of the encapsulation layer is positioned in the area between the pad electrodes in the non-display area.

This application claims priority to Korean Patent Application No. 10-2024-0072323, filed on Jun. 3, 2024, and all the benefits accruing therefrom under 35 U.S.C. § 119, the content of which in its entirety is herein incorporated by reference.

### BACKGROUND

### (a) Field

The invention relates to a display device, and more particularly to a display device that prevents exposure of the pad and a manufacturing method thereof.

### (b) Description of the Related Art

A display device is a device that displays images, and recently, an organic light emitting diode display which is a type of emissive display device, has been attracting attention.

The organic light emitting diode display has a self-luminous characteristic, and because the organic light emitting diode display does not need a separate light source, unlike a liquid crystal display, it can have a relatively small thickness and weight. In addition, the organic light emitting diode display exhibits high-quality characteristics such as low power consumption, high luminance, high response speed, etc.

Generally, the light emitting diode display includes a substrate, a plurality of thin-film transistors disposed on the substrate, a plurality of insulating layers disposed between wires for configuring the thin-film transistors, and a light emitting element connected to the thin-film transistor.

In addition to the light emitting element, the display device includes a circuit and a pad for inputting signals used to control the light emitting element and the circuit. The pad may be used to control the light emitting elements and the circuits, and may also be used for a lighting inspection in the manufacturing process of the display device.

### SUMMARY

The embodiments are intended to provide a display device and a manufacturing method thereof that prevents exposure of the pads.

A display device, according to an embodiment, includes a substrate including a display area and a non-display area, a light emitting element positioned in the display area and an encapsulation layer overlapping the light emitting element and a plurality of pad electrodes positioned in the non-display area of the substrate, wherein the side of the pad electrode that is facing the edge of the substrate is covered with a middle layer, the residual layer of the encapsulation layer is not positioned on the upper surface of the pad electrode, and the residual layer of the encapsulation layer is positioned in the area between the pad electrodes in the non-display area.

In an embodiment, the display area may further include a source electrode and a drain electrode positioned on the same layer as the pad electrode.

In an embodiment, an insulating layer positioned above the middle layer and a first electrode positioned above the insulating layer may be further included, wherein the middle layer may overlap the drain electrode, and the first electrode may be in contact with the drain electrode at the opening of the middle layer.

In an embodiment, a manufacturing method of a display device includes preparing a substrate including a display area and a non-display area, forming a pad electrode and a lighting inspection electrode in the non-display area of the substrate, forming a connection electrode connecting the pad electrode and the lighting inspection electrode, removing the connection electrode, and cutting the substrate to remove the lighting inspection electrode.

In an embodiment, the pad electrode and the connection electrode may include different materials.

In an embodiment, the lighting inspection electrode and the connection electrode may include different materials.

In an embodiment, after removing the connection electrode, processing the substrate with a laser may be further included.

In an embodiment, in cutting the substrate to remove the lighting inspection electrode, the area treated with the laser may be cut.

In an embodiment, after cutting the substrate to remove the lighting inspection electrode, the side of the pad electrode facing the edge of the substrate may not be exposed.

In an embodiment, further including forming an encapsulation layer in the display area of the substrate between forming the connection electrode connecting the pad electrode and the lighting inspection electrode and removing the connection electrode.

In an embodiment, in forming the encapsulation layer in the display area of the substrate, the residual layer of the encapsulation layer may be formed in the non-display area of the substrate.

In an embodiment, in removing the connection electrode, the residual layer of the connecting electrode and an encapsulation layer positioned on the connection electrode may be removed.

In an embodiment, after removing the connection electrode, the residual layer of the encapsulation layer may not be positioned on the upper surface of the pad electrode.

In an embodiment, after removing the connection electrode, the residual layer of the encapsulation layer may be positioned in the area between the pad electrodes.

In an embodiment, a source electrode and a drain electrode may be positioned in the display area, and the source electrode, the drain electrode, the pad electrode, and the lighting inspection electrode may be formed by the same process.

In an embodiment, forming a middle layer on the pad electrode and the lighting inspection electrode may be further included between forming the pad electrode and the lighting inspection electrode in the non-display area of the substrate and forming the connection electrode connecting the pad electrode and the lighting inspection electrode.

In an embodiment, forming openings in the middle layer that overlap the pad electrode and the lighting inspection electrode, respectively, may be further included, wherein the pad electrode and the connection electrode may be in contact at the opening, and wherein the lighting inspection electrode and the connection electrode may be in contact at the opening.

In an embodiment, in removing the connection electrode, the pad electrode and the lighting inspection electrode may not be removed.

In an embodiment, the display area of the substrate may include a plurality of transistors and light emitting elements connected thereto.

In an embodiment, the display device may be a rollable display device.

According to an embodiment, a display device that prevents the exposure of the pad and the manufacturing method thereof are provided.

According to embodiments, an electronic device includes the display device as described herein.

The electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IOT) device, a smartwatch, a watch phone, and/or a head-mounted display (HMD).

### BRIEF DESCRIPTION OF THE DRAWINGS

FIG. 1 illustrates a display device, according to an embodiment.

FIG. 2 illustrates a cross-section view of the display device in FIG. 1 taken along a line I-I′, according to an embodiment.

FIG. 3 illustrates a plan view of an area A in FIG. 2, according to an embodiment.

FIG. 4 illustrates a cross-section view of a display device, according to a comparative example.

FIG. 5 illustrates a cross-section view of a display device in which an electrode for lighting inspection has been removed, according to the embodiment of FIG. 4.

FIG. 6 illustrates a plan view of an area B in FIG. 5, according to an embodiment.

FIG. 7 illustrates a display device, according to an embodiment.

FIG. 8 illustrates a display part of a display device that is rolled and stored in a housing part, according to an embodiment.

FIG. 9 illustrates a process of rolling or unfolding a display part of a display device by a roller positioned inside a housing part, according to an embodiment.

FIG. 10 illustrates a manufacturing process of a display device, according to an embodiment.

FIG. 11 illustrates a manufacturing process of a display device, according to an embodiment.

FIG. 12 illustrates a manufacturing process of a display device, according to an embodiment.

FIG. 13 illustrates a manufacturing process of a display device, according to an embodiment.

FIG. 14 illustrates a forming process of an encapsulation layer in a display device, according to a comparative example.

FIG. 15 illustrates a forming process of an encapsulation layer in a display device, according to a comparative example.

FIG. 16 illustrates a forming process of an encapsulation layer in a display device, according to an embodiment.

FIG. 17 illustrates a forming process of an encapsulation layer in a display device, according to an embodiment.

FIG. 18 illustrates an upper surface of an encapsulation layer and a pad electrode in a display device, according to the embodiment of FIG. 4.

FIG. 19 illustrates an upper surface of an encapsulation layer and a pad electrode in a display device, according to an embodiment.

FIG. 20 illustrates an upper surface of an encapsulation layer and a pad electrode in a display device, according to an embodiment.

### DETAILED DESCRIPTION

The invention will be described more fully hereinafter with reference to the accompanying drawings, in which exemplary embodiments of the invention are shown. As those skilled in the art would realize, the described embodiments may be modified in various different ways, all without departing from the spirit or scope of the invention.

The drawings and description are to be regarded as illustrative in nature and not restrictive, and like reference numerals designate like elements throughout the specification.

Further, in the drawings, a size and thickness of each element are randomly represented for better understanding and ease of description, and the invention is not limited thereto. In the drawings, the thickness of layers, films, panels, areas, etc., are exaggerated for clarity. In the drawings, for understanding and ease of description, the thickness of some layers and areas is exaggerated.

It should be understood that when an element such as a layer, film, area, or substrate is referred to as being “on” another element, it can be directly on the other element or intervening elements may also be present. In contrast, when an element is referred to as being “directly on” another element, there are no intervening elements present. Further, the word “over” or “on” means positioning on or below the object portion, but does not essentially mean positioning on the upper side of the object portion based on a gravity direction.

In addition, unless explicitly described to the contrary, the word “comprise,” and variations such as “comprises” or “comprising,” should be understood to imply the inclusion of stated elements but not the exclusion of any other elements.

Further, throughout the specification, the term “in a plan view” means a case where a target portion is viewed from above, and the term “in cross-section” means a case where a cross-section taken by vertically cutting a target portion is viewed from the side.

A display device according to an embodiment can be applied to various electronic devices. The electronic device according to one embodiment includes the display device described below, and may further include a module or device having additional functions in addition to the display device.

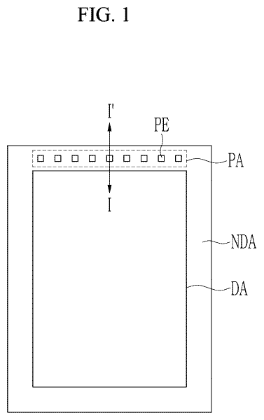

Hereinafter, a display device and a manufacturing method thereof, according to an embodiment, will be described below with reference to drawings. FIG. 1 illustrates a display device, according to an embodiment.

In an embodiment and referring to FIG. 1, the display device includes a display area DA and a non-display area NDA. The display area DA is an area where a plurality of pixels are positioned to display images, and the non-display area NDA is an area where drivers and pads for operating the pixels of the display area DA are positioned. Referring to FIG. 1, a pad area PA may be positioned in the non-display area NDA and a pad electrode PE may be positioned in the pad area PA.

The display device, according to an embodiment, may be a rollable display device. However, this is only an example, and the invention is not limited thereto. Additionally, the display device, according to an embodiment, may include one substrate, but this is only an example and is not limited thereto.

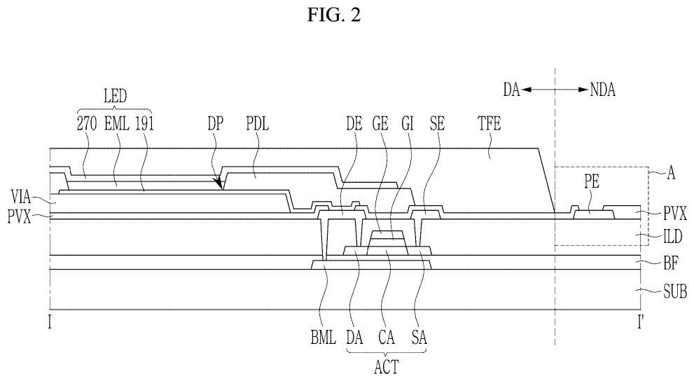

FIG. 2 is a cross-section of a display device of FIG. 1 taken along a line I-I′ as shown in FIG. 1. In an embodiment and referring to FIG. 2, a substrate SUB is positioned and may include plastic or glass.

In an embodiment and referring to FIG. 2, a light blocking layer BML is positioned on the substrate SUB, where the light blocking layer BML may reduce a leakage current and a characteristic deterioration by preventing an external light from reaching a channel area CA of a semiconductor layer ACT. The light blocking layer BML may be electrically connected to a drain electrode DE.

In an embodiment, a buffer layer BF is positioned on the light blocking layer BML and may include an inorganic insulating material and/or an organic insulating material such as silicon nitride (SiNx), silicon oxide (SiO2), silicon oxynitride (SiOxNy), the like, where “X” may be 1 to 4.

In an embodiment, the semiconductor layer ACT is positioned on the buffer layer BF and includes a source area SA, the channel area CA, and a drain area DA. The semiconductor layer ACT may include any one of amorphous silicon, polycrystalline silicon, monocrystalline silicon, and an oxide semiconductor. In an embodiment, the semiconductor layer ACT may include an oxide semiconductor. However, the invention is not limited thereto, and in another embodiment, the semiconductor layer ACT may include a polycrystalline semiconductor.

In an embodiment, a gate insulating pattern GI may be positioned to overlap the channel area CA of the semiconductor layer. The gate insulating pattern GI may not substantially overlap the conductive area of the semiconductor layer.

In an embodiment, a gate electrode GE may be positioned on the gate insulating pattern GI and may overlap the channel area CA of the semiconductor layer ACT in the vertical direction to the substrate SUB. The gate electrode GE, the semiconductor layer ACT, the source electrode SE, and the drain electrode DE may form a transistor.

In an embodiment, an interlayer insulating layer ILD may be positioned on the semiconductor layer and may include silicon nitride (SiNx), silicon oxide (SiO2), or silicon oxynitride (SiOxNy). The interlayer insulating layer ILD may be a multilayer including silicon nitride (SiNx), silicon oxide (SiO2), or silicon oxynitride (SiOxNy).

In an embodiment, a source electrode SE, a drain electrode DE, and a pad electrode PE may be positioned on the interlayer insulating layer ILD. The source area SA of the semiconductor layer may be connected to the source electrode SE, and the drain area DA may be connected to the drain electrode DE. The drain electrode DE may be electrically connected to the light blocking layer BML. Although not shown in FIG. 2, the source electrode SE and the drain electrode DE may have a multi-layer structure. In an embodiment, as shown in FIG. 2, the pad electrode PE may be positioned in the non-display area NDA.

In an embodiment and referring to FIG. 2, the side of the pad electrode PE may not be exposed and may be covered by a middle layer PVX. In addition, as will be explained separately later, in the display device according to an embodiment, the residual layer of an encapsulation layer TFE is not positioned on the upper surface of the pad electrode PE. According to an embodiment, the display device is characterized in that the side of the pad electrode PE is not exposed. The specific structure will be described later.

In an embodiment and referring to FIG. 2, a first electrode 191 may be positioned on the middle layer PVX and may be electrically connected to the drain electrode DE. An insulating layer VIA may be positioned between the first electrode 191 and the middle layer PVX. The insulating layer VIA may include an organic material.

In an embodiment, a barrier rib PDL may be positioned on the first electrode 191 and may include an opening DP that overlaps the first electrode 191. The light emitting layer EML may be positioned within the opening DP, and a second electrode 270 may be positioned on the light emitting layer EML. The first electrode 191, the light emitting layer EML, and the second electrode 270 may constitute a light emitting element LED.

In an embodiment and referring to FIG. 2, the encapsulation layer TFE may be positioned on the second electrode 270. The encapsulation layer TFE may overlap most structures of the display device, but may not overlap the pad electrode PE. Therefore, a driver for driving the display device, etc. may be connected to the pad electrode PE.

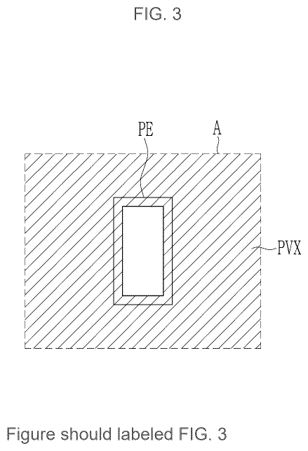

As shown in FIG. 2, the display device, according to an embodiment, is characterized in that the side of the pad electrode PE is not exposed and is covered by the middle layer PVX. FIG. 3 illustrates a plan view of an area marked by A in FIG. 2. In an embodiment and as shown in FIG. 3, the side of the pad electrode PE may not be exposed at the edge of the substrate SUB.

In addition, the display device, according to an embodiment, is characterized in that the residual layer of the encapsulation layer TFE is not positioned on the upper surface of the pad electrode PE. This structure is derived by connecting a lighting inspection electrode LE for the lighting inspection of the display panel and the pad electrode PE with a separate connection electrode CE, and the structure and the manufacturing method will be explained in detail later.

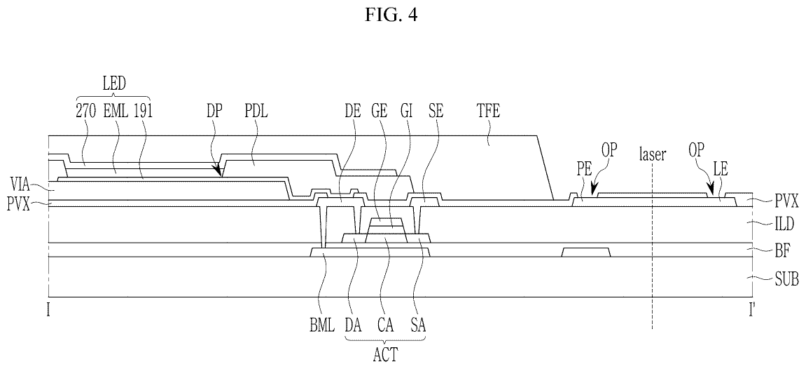

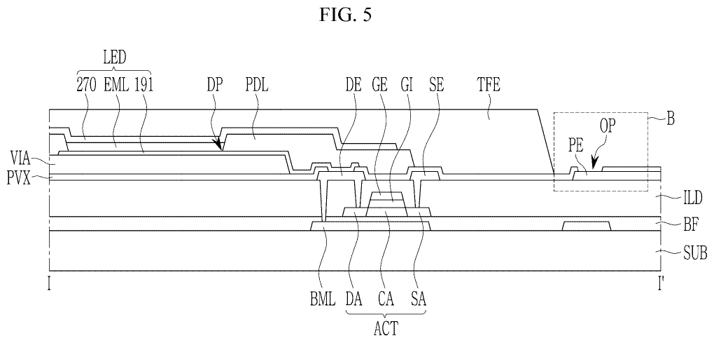

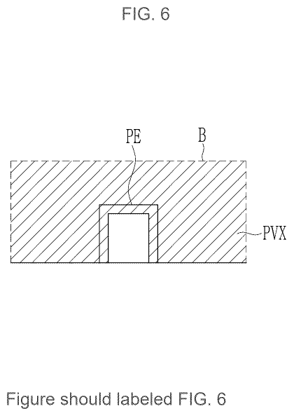

FIG. 4 illustrates a display device, according to a comparative example. Referring to FIG. 4, the display device, according to the comparative example, is the same as the embodiment of FIG. 2 except for including a pad electrode PE and a lighting inspection electrode LE. Detailed descriptions of the same components are omitted. Referring to FIG. 4, the pad electrode PE and the lighting inspection electrode LE are connected together. In other words, the pad electrode PE and the lighting inspection electrode LE are integrally formed, and an opening OP is formed in the middle layer PVX to expose the pad electrode PE and the lighting inspection electrode LE, respectively. As explained previously, the pad electrode PE is the area where the driver for driving the display device is connected, and the lighting inspection electrode LE is an electrode used to check whether the display device is lighting properly during the manufacturing process of the display device. Therefore, the lighting inspection electrode LE is removed in the manufacturing process. In FIG. 4, the part where the lighting inspection electrode LE is removed is shown as a dotted line. FIG. 5 illustrates that a lighting inspection electrode LE is removed in the display device, according to the embodiment of FIG. 4. FIG. 6 is a view showing a plane of an area marked by B in FIG. 5. Referring to FIG. 5 and FIG. 6, the side of the pad electrode PE is exposed at the edge of the substrate SUB during the removal process of the lighting inspection electrode LE. Accordingly, the side of the pad electrode PE that is exposed in this way may be damaged.

However, in the display device, according to an embodiment, the side of the pad electrode PE is covered with the middle layer PVX, thereby preventing damage to the pad electrode PE. If the side of the pad electrode PE is covered like this, it may be difficult to connect to the lighting inspection electrode LE during the manufacturing process of the display device. However, according to an embodiment, the display device connects the pad electrode PE and the lighting inspection electrode LE with a separate connection electrode.

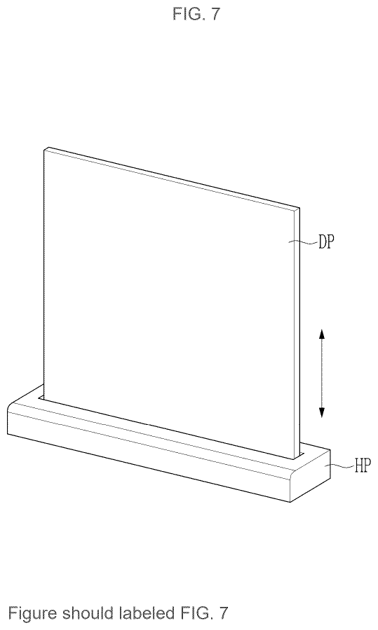

According to an embodiment, the display device may be a rollable display device. FIG. 7 illustrates a display device, according to an embodiment. Referring to FIG. 7, the display device, according to an embodiment, includes a display part DP and a housing part HP. The display part DP is a component that displays an image to the user and may include a display element, and circuits and wires to drive the display element. At this time, the display device, according to an embodiment, may be a rollable display device, and the display part DP may be rolled, folded, or unfolded. The housing part HP is a housing where the display part DP may be housed. The display part DP may be rolled and housed in the housing part HP, and unfolded to display the images outside the housing part HP.

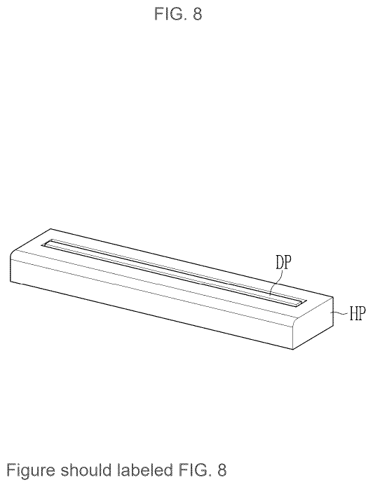

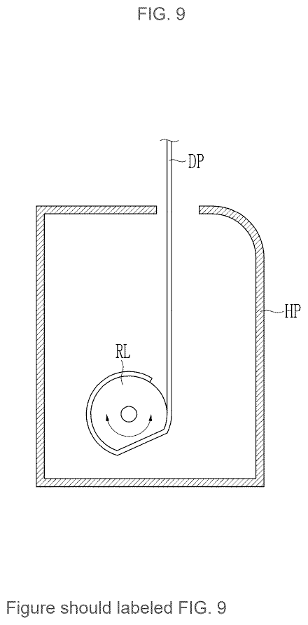

FIG. 7 illustrates a display part DP in an unfolded state, according to an embodiment. FIG. 8 illustrates a display part DP being rolled and housed in a housing part HP, according to an embodiment. FIG. 9 illustrates a process of rolling or unfolding a display part DP by a roller RL positioned inside a housing part HP, according to an embodiment.

In an embodiment and as shown in FIG. 9, the roller RL may be positioned inside the housing part HP, and the display part DP may be positioned appropriately according to the usage environment while being wound or pulled around the roller RL. In other words, when the display part DP is fully wrapped around the roller RL, as shown in FIG. 8, the display part DP may be housed in the housing part HP. Also, in the case where the display part DP in the roller RL is fully unfolded, as shown in FIG. 7, the display part DP is positioned outside the housing part HP and may display an image. In this rollable display device, the substrate SUB must be rolled, so an etching process for the substrate SUB is required. In this etching process, there is a problem with the side of the pad electrode PE being exposed during the removal process of the lighting inspection electrode LE, but according to an embodiment, the side of the pad electrode PE is not exposed at the edge of the substrate SUB in the display device.

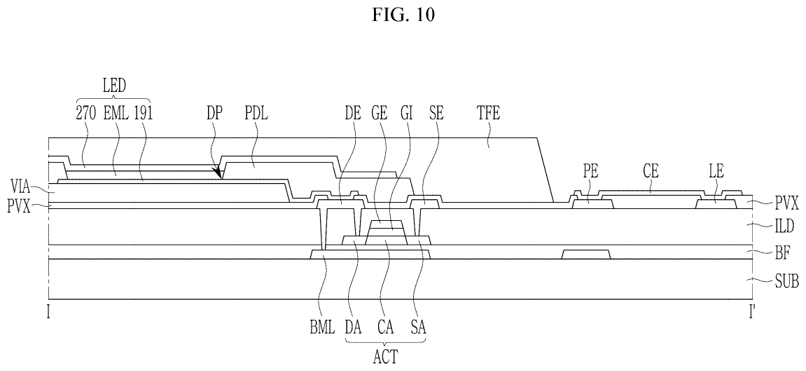

FIG. 10 to FIG. 13 illustrate a manufacturing process of a display device, according to an embodiment.

Referring to FIG. 10, a display panel as shown in FIG. 10 is prepared. The description of the display area DA is the same as described in FIG. 2, so it is omitted.

In an embodiment and referring to FIG. 10, a pad electrode PE and a lighting inspection electrode LE are positioned in the non-display area NDA, respectively. As shown in FIG. 10, the pad electrode PE and the lighting inspection electrode LE are not connected as one and are separated from each other. However, the connecting electrode CE is positioned above the pad electrode PE and the lighting inspection electrode LE, and the pad electrode PE and the lighting inspection electrode LE are connected by the connecting electrode CE. At this time, the material of the connection electrode CE is not limited, but may include a material different from the pad electrode PE and the lighting inspection electrode LE. This is because the connection electrode CE is selectively etched in a subsequent process. That is, the connection electrode CE preferably includes a material that has an etch selectivity for the pad electrode PE and the lighting inspection electrode LE.

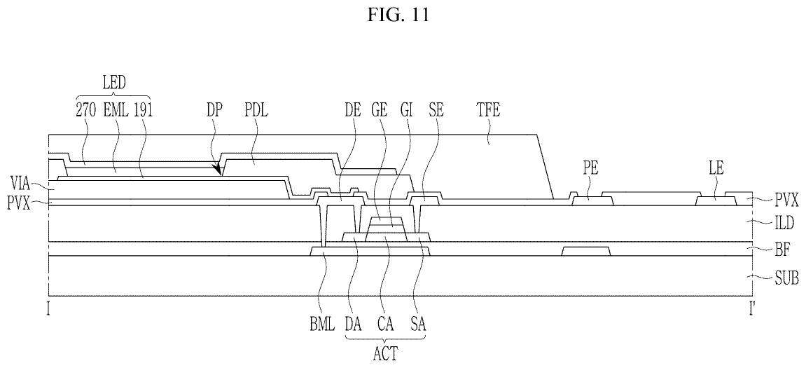

Next, according to an embodiment and referring to FIG. 11, the connection electrode CE is removed. As previously explained, the connection electrode CE includes a material that has the etch selectivity from the pad electrode PE and the lighting inspection electrode LE, so only the connection electrode CE may be removed and the pad electrode PE and lighting inspection electrode LE may not be removed.

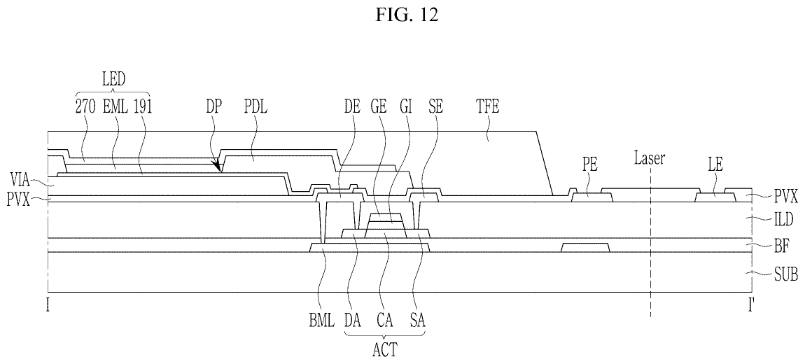

Next, according to an embodiment and referring to FIG. 12, the incision surface is pretreated with a laser, where the area where pretreatment is performed is the area located between the pad electrode PE and the lighting inspection electrode LE.

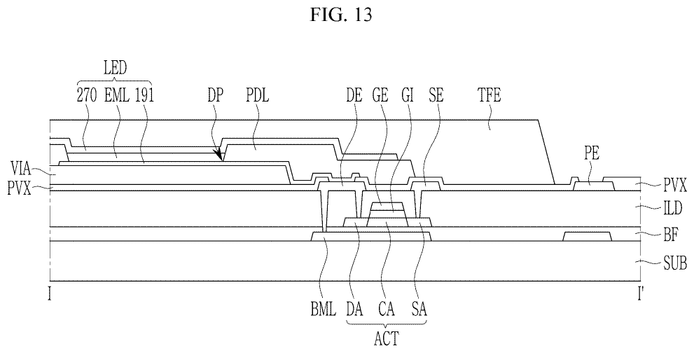

Next, according to an embodiment and referring to FIG. 13, the display device is cut along the laser treatment area. Through this process, the lighting inspection electrode LE may be removed.

In this way, in the display device and the manufacturing method according to an embodiment, the pad electrode PE and the lighting inspection electrode LE are connected through the connection electrode CE during the manufacturing process. Afterwards, the connection electrode CE is removed and the lighting inspection electrode LE is removed, so the side of the pad electrode PE may not be exposed and the pad electrode PE may be protected.

In an embodiment and as shown in FIG. 10 to FIG. 13, during the manufacturing process, since the connection electrode CE covers the upper surfaces of the pad electrode PE and the lighting inspection electrode LE, the residual layer of the encapsulation layer TFE may not be positioned on the upper surface of the pad electrode PE.

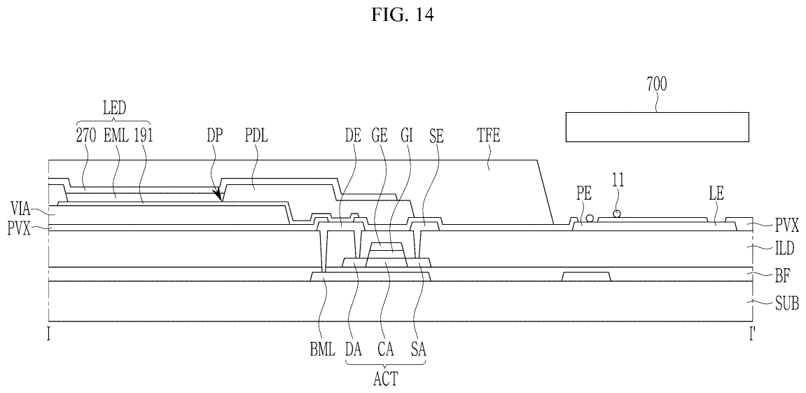

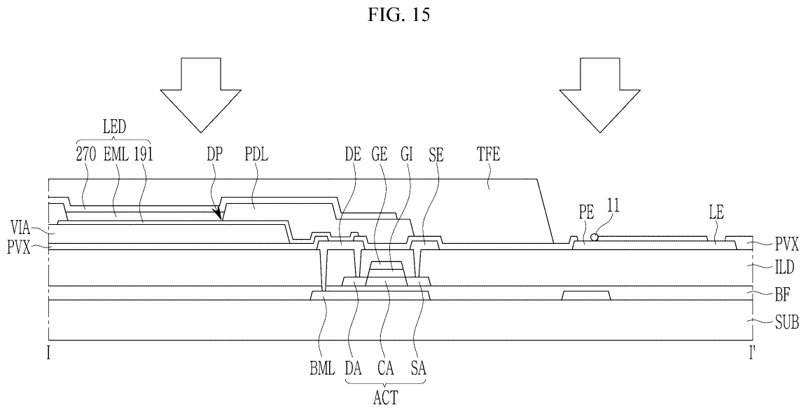

FIG. 14 and FIG. 15 illustrate a forming process of an encapsulation layer TFE in a display device, according to a comparative example. FIG. 14 illustrates a comparative example in which the pad electrode PE and the lighting inspection electrode LE are connected together. Referring to FIG. 14, when forming the encapsulation layer TFE in the display area DA of the display device, a mask 700 is used. At this time, the mask 700 is positioned on the pad electrode PE and the lighting inspection electrode LE, so the encapsulation layer TFE is not directly formed, but a residual layer 11 of the encapsulation layer TFE may be formed on the pad electrode PE and the lighting inspection electrode LE through the side of the mask 700. Referring to FIG. 15, the residual layer 11 of the encapsulation layer TFE formed on the pad electrode PE and the lighting inspection electrode LE is removed through subsequent full-surface dry etching, but a fine residual layer 11 may remain on the pad electrode PE.

However, in the display device according to an embodiment, the connection electrode CE is positioned on the upper surface of the pad electrode PE and the lighting inspection electrode LE, and then the connection electrode CE is removed, so that the residual layer of the encapsulation layer TFE is not positioned on the upper surface of the pad electrode PE and the lighting inspection electrode LE.

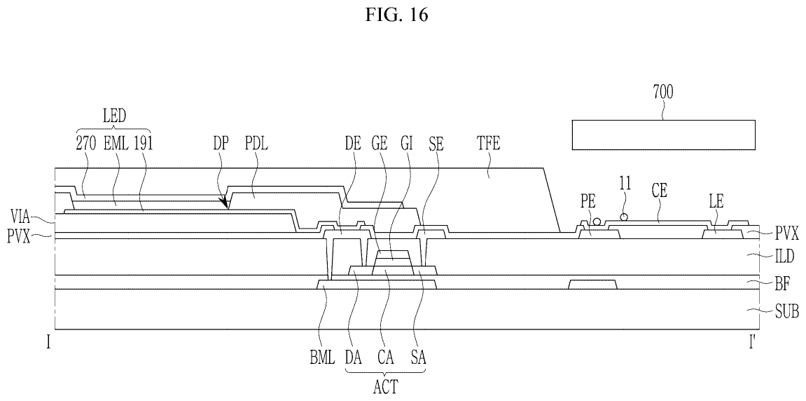

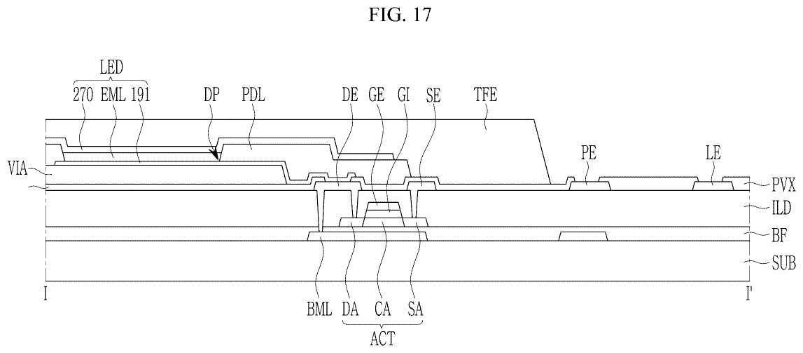

FIG. 16 and FIG. 17 illustrate a forming process of an encapsulation layer TFE in a display device, according to an embodiment. In an embodiment and referring to FIG. 16, a connection electrode CE is positioned on a pad electrode PE and a lighting inspection electrode LE which are separated from each other. Therefore, the residual layer 11 formed in the forming process of the encapsulation layer TFE is positioned on the connection electrode CE.

Next, in an embodiment and referring to FIG. 17, the connection electrode CE is removed. At this time, the residual layer of the encapsulation layer TFE formed on the connection electrode CE is also removed, so there is no residual layer of the encapsulation layer TFE on the pad electrode PE and the lighting inspection electrode LE.

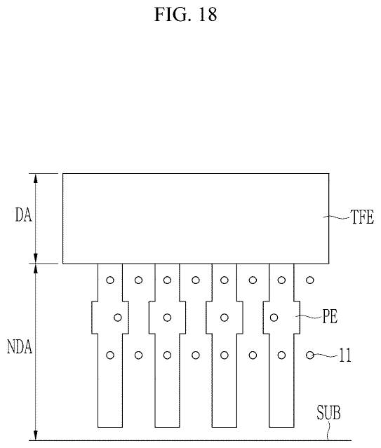

FIG. 18 illustrates an upper surface of an encapsulation layer TFE and a pad electrode PE in a display device, according to the embodiment of FIG. 4. As shown in FIG. 18, the residual layer 11 of the encapsulation layer TFE may remain in the area between the upper surface of the pad electrode PE and the neighboring pad electrode PE.

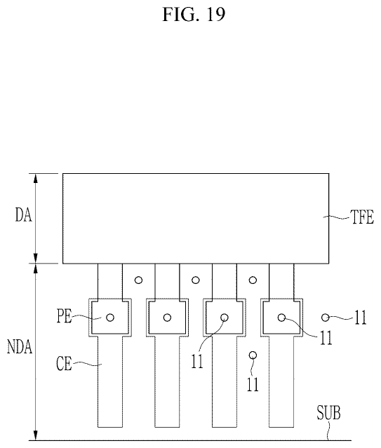

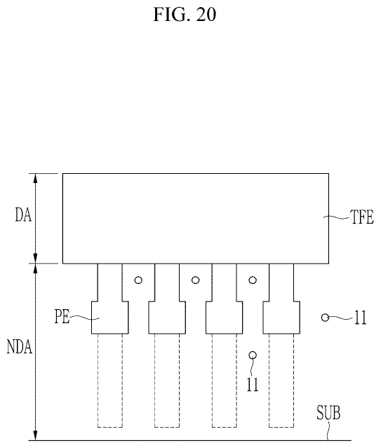

FIG. 19 and FIG. 20 illustrate an upper surface of an encapsulation layer TFE and a pad electrode PE in a display device, according to an embodiment

FIG. 19 illustrates an embodiment where a connection electrode CE is in a formed state, where the residual layer 11 of the encapsulation layer may exist in the space between the upper surface of the connection electrode CE and the neighboring pad electrode PE.

In an embodiment and as shown in FIG. 20, after the connection electrode CE is removed, the residual layer 11 of the encapsulation layer, which was positioned on the upper surface of the connection electrode CE, is removed along with the removal of the connection electrode CE, so no residual layer of the encapsulation layer is present on the pad electrode PE. The residual layer 11 of the encapsulation layer may be present in the area between the pad electrodes PE. FIG. 20 illustrates the edge of the substrate SUB, and the residual layer 11 may not be positioned on the edge portion of the substrate SUB. That is, as shown in FIG. 20, the residual layer 11 may be mainly positioned in the area away from the edge of the substrate SUB in the non-display area—i.e., in the area close to the display area. As shown in FIG. 20, the residual layer 11 may be positioned in the area located between the pad electrodes PE.

As described above, the display device and the manufacturing method according to an embodiment, connect the pad electrode and the lighting inspection electrode with the connection electrode, and cut the lighting inspection electrode after removing the connection electrode. Therefore, since the side of the pad electrode is not exposed, damage to the pad electrode may be prevented, and since the upper surface of the pad electrode is covered by the connection electrode during the manufacturing process, the residual layer of the encapsulation layer may not be positioned on the upper surface of the pad electrode.

According to embodiments, an electronic device includes the display device as described herein.

The electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IOT) device, a smartwatch, a watch phone, and/or a head-mounted display (HMD).

While the invention has been described in connection with what is considered to be practical exemplary embodiments, it is to be understood that the invention is not limited to the embodiments disclosed herein, but, rather, is intended to cover various modifications and equivalent arrangements included within the spirit and scope of the invention. Therefore, it will be understood by one of ordinary skill in the art to which the invention belongs that the invention may be implemented in other specific embodiments than those described herein without changing the technical spirit or essential features of the invention. Additionally, it is to be understood that the exemplary embodiments described above are illustrative rather than being restrictive in all aspects. The disclosed embodiments of the invention are used in a generic and descriptive sense only and not for purposes of limitation. Each component specifically shown in the embodiments of the invention can be implemented by modification, and such modifications and differences related to invention should be construed as being included in the scope of the invention. Moreover, the embodiments or parts of the embodiments may be combined in whole or in part without departing from the scope of the invention.

What is claimed is:

1. A display device comprising:
a substrate including a display area and a non-display area;
a light emitting element positioned in the display area and an encapsulation layer overlapping the light emitting element; and
a plurality of pad electrodes positioned in the non-display area,
wherein a side of a pad electrode of the plurality of pad electrodes facing an edge of the substrate is covered with an interlayer,
wherein a residual layer of the encapsulation layer is not positioned on an upper surface of the pad electrode, and
wherein the residual layer of the encapsulation layer is positioned in an area disposed between the pad electrodes.

2. The display device of claim 1, wherein:
the display area further includes a source electrode and a drain electrode positioned on a same layer as the pad electrode.
and further comprising:
an insulating layer positioned over the interlayer; and
a first electrode positioned above the insulating layer,
wherein the interlayer overlaps the drain electrode, and
wherein the first electrode is in contact with the drain electrode at an opening of the interlayer.

3. A method for manufacturing a display device comprising:
preparing a substrate including a display area and a non-display area,
forming a pad electrode and a lighting inspection electrode in the non-display,
forming a connection electrode connecting the pad electrode and the lighting inspection electrode,
removing the connection electrode, and
cutting the substrate to remove the lighting inspection electrode.

4. The method of claim 3, wherein:
the pad electrode and the connection electrode include different materials.

5. The method of claim 3, wherein:
the lighting inspection electrode and the connection electrode include different materials.

6. The method of claim 3, further comprising:
after removing the connection electrode,
processing the substrate with a laser.

7. The method of claim 6, wherein:
in cutting the substrate to remove the lighting inspection electrode,
the area treated with the laser is cut.

8. The method of claim 3, wherein:
after cutting the substrate to remove the lighting inspection electrode,
a side of the pad electrode facing an edge of the substrate is not exposed.

9. The method of claim 3, further comprising:
between the step of forming the connection electrode connecting the pad electrode and the lighting inspection electrode and removing the connection electrode,
forming an encapsulation layer in the display area of the substrate.

10. The method of claim 9, wherein:
in forming the encapsulation layer in the display area,
a residual layer of the encapsulation layer is formed in the non-display area,
wherein in removing the connection electrode,
a residual layer of the encapsulation layer positioned on the connection electrode is removed,
wherein after removing the connection electrode,
the residual layer of the encapsulation layer is not positioned on an upper surface of the pad electrode,.
wherein after removing the connection electrode,
the residual layer of the encapsulation layer is positioned in an area between the pad electrodes.

11. The method of claim 3, wherein:
a source electrode and a drain electrode are positioned in the display area,
wherein the source electrode, drain electrode, the pad electrode, and the lighting inspection electrode are formed by the same process.

12. The method of claim 3, further comprising:
between the step of forming the pad electrode and the lighting inspection electrode in the non-display and forming the connection electrode connecting the pad electrode and the lighting inspection electrode,
forming an interlayer on the pad electrode and the lighting inspection electrode.

13. The method of claim 12, further comprising:
forming openings in the interlayer that overlap the pad electrode and the lighting inspection electrode, respectively,
wherein the pad electrode and the connection electrode are in contact at the openings in the interlayer, and
wherein the lighting inspection electrode and the connection electrode are in contact at the openings in the interlayer.

14. The method of claim 3, wherein:
in the removing of the connection electrode,
the pad electrode and the lighting inspection electrode are not removed.

15. The method of claim 3, wherein:
the display area includes a plurality of transistors and light emitting elements connected thereto.

16. The method of claim 3, wherein:
the display device is a rollable display device.

17. An electronic device comprising:
a display device, wherein the display device includes,
a substrate including a display area and a non-display area;
a light emitting element positioned in the display area and an encapsulation layer overlapping the light emitting element; and
a plurality of pad electrodes positioned in the non-display area,
wherein a side of a pad electrode of the plurality of pad electrodes facing an edge of the substrate is covered with an interlayer,
wherein a residual layer of the encapsulation layer is not positioned on an upper surface of the pad electrode, and
wherein the residual layer of the encapsulation layer is positioned in an area disposed between the pad electrodes.

18. The electronic device of claim 17, wherein:
the display area further includes a source electrode and a drain electrode positioned on a same layer as the pad electrode.

19. The electronic device of claim 17, wherein the display device further includes,
an insulating layer positioned over the interlayer; and
a first electrode positioned above the insulating layer,
wherein the interlayer overlaps the drain electrode, and
wherein the first electrode is in contact with the drain electrode at an opening of the interlayer.

20. The electronic device of claim 17,
wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IOT) device, a smartwatch, a watch phone, or a head-mounted display (HMD).
